(19) United States
(12) Patent Application Publication
(10) Pub. No.: US 2025/0189781 A1
(43) Pub. Date: Jun. 12, 2025

(54) VIBRATION DEVICE

(71) Applicant: Murata Manufacturing Co., Ltd., Nagaokakyo-shi (JP)

(72) Inventors: Yuka TANAKA, Nagaokakyo-shi (JP); Yuuki ISHII, Nagaokakyo-shi (JP); Shigehisa YAGO, Nagaokakyo-shi (JP)

(21) Appl. No.: 19/052,378

(22) Filed: Feb. 13, 2025

Related U.S. Application Data
(63) Continuation of application No. PCT/JP2023/021009, filed on Jun. 6, 2023.

(30) Foreign Application Priority Data
Sep. 28, 2022 (JP) 2022-155068

(51) Int. Cl. G02B 27/00; G02B 7/02; H10N 30/20

(52) U.S. Cl. CPC G02B 27/0006; G02B 7/021; H10N 30/20

(57) ABSTRACT

A vibration device that includes: a vibrator; a piezoelectric element located at a first end of the vibrator in a first direction; a light-transmitting element located at a second end of the vibrator in the first direction; a holding portion that holds the second end of the vibrator and the light-transmitting element in the first direction; a first member between the light-transmitting element and the holding portion and connected to the light-transmitting element and the holding portion; and a second member between the light-transmitting element and the vibrator and connected to the light-transmitting element and the vibrator, wherein a thickness of the first member is equal to or more than a thickness of the second member.

### CROSS REFERENCE TO RELATED APPLICATIONS

The present application is a continuation of International application No. PCT/JP2023/021009, filed Jun. 6, 2023, which claims priority to Japanese Patent Application No. 2022-155068, filed Sep. 28, 2022, the entire contents of each of which are incorporated herein by reference.

### TECHNICAL FIELD

The present disclosure relates to a vibration device.

### BACKGROUND ART

Patent Document 1 discloses a droplet removal device including an optical element including a domed portion, a vibrating member configured to generate bending vibrations in the domed portion, a vibration controller configured to control the vibrating member, and a drip-proof seal configured to inhibit droplets from entering the droplet removal device.

Patent Document 1: Japanese Unexamined Patent Application Publication No. 2017-170303

### SUMMARY OF THE DISCLOSURE

The droplet removal device described in Patent Document 1 yet has room for improvement of inhibiting droplets from entering the droplet removal device and of reducing the stress applied to a light-transmitting element.

An object of the present disclosure is to provide a vibration device capable of inhibiting droplets from entering the vibration device and of reducing the stress applied to a light-transmitting element.

A vibration device according to an aspect of the present disclosure includes: a vibrator; a piezoelectric element at a first end of the vibrator in a first direction; a light-transmitting element at a second end of the vibrator in the first direction; a holding portion that holds the second end of the vibrator and the light-transmitting element in the first direction; a first member between the light-transmitting element and the holding portion and connected to the light-transmitting element and the holding portion; and a second member between the light-transmitting element and the vibrator and connected to the light-transmitting element and the vibrator. A thickness of the first member is equal to or more than a thickness of the second member.

A vibration device according to another aspect of the present disclosure includes: a vibrator; a piezoelectric element at a first end of the vibrator in a first direction; a light-transmitting element at a second end of the vibrator in the first direction; a holding portion that holds the second end of the vibrator and the light-transmitting element in the first direction; a first member between the light-transmitting element and the holding portion and connected to the light-transmitting element and the holding portion; and a second member between the light-transmitting element and the vibrator and connected to the light-transmitting element and the vibrator. A Young's modulus of the first member is equal to or less than a Young's modulus of the second member.

The vibration device according to each of the aspects is capable of inhibiting droplets from entering the vibration device and of reducing the stress applied to the light-transmitting element.

### BRIEF DESCRIPTION OF THE DRAWINGS

FIG. 1 is a perspective view illustrating a vibration device in an embodiment of the present disclosure.

FIG. 2 is a sectional view taken along line II-II in FIG. 1.

FIG. 3 is a partial enlarged view of FIG. 2 for describing a first member.

FIG. 4 is a partial enlarged view of FIG. 2 for describing a second member.

FIG. 5 is a graph illustrating the relationship between the respective thicknesses of the first member and the second member and the maximum displacement amount of a top portion of a lens.

FIG. 6 is a graph illustrating the relationship between the respective thicknesses of the first member and the second member and the maximum thermal stress applied to the lens.

FIG. 7 is a contour diagram illustrating the thermal stress applied to the lens.

FIG. 8 is a graph illustrating the relationship between the respective Young's moduli of the first member and the second member and the maximum displacement amount of the top portion of the lens.

FIG. 9 is a graph illustrating the relationship between the respective Young's moduli of the first member and the second member and the maximum thermal stress applied to the lens.

FIG. 10 is a sectional view illustrating a first modification example of the vibration device in FIG. 1.

FIG. 11 is a sectional view illustrating a second modification example of the vibration device in FIG. 1.

FIG. 12 is a sectional view illustrating a third modification example of the vibration device in FIG. 1.

FIG. 13 is a sectional view illustrating a fourth modification example of the vibration device in FIG. 1.

FIG. 14 is a sectional view illustrating a fifth modification example of the vibration device in FIG. 1.

FIG. 15 is a sectional view illustrating a sixth modification example of the vibration device in FIG. 1.

FIG. 16 is a sectional view illustrating a seventh modification example of the vibration device in FIG. 1.

FIG. 17 is a sectional view taken along line XVII-XVII in FIG. 13.

FIG. 18 is a sectional view illustrating an eighth modification example of the vibration device in FIG. 1.

### DESCRIPTION OF THE PREFERRED EMBODIMENTS

Various aspects of the present disclosure will be described.

A vibration device according to Aspect 1 of the present disclosure includes: a vibrator; a piezoelectric element located at one end of the vibrator in a first direction; a light-transmitting element located at another end of the vibrator in the first direction; a holding portion that holds, along with the other end of the vibrator, the light-transmitting element in the first direction; a first member that is located between the light-transmitting element and the holding portion and that is connected to the light-transmitting element and the holding portion; and a second member that is located between the light-transmitting element and the vibrator and that is connected to the light-transmitting element and the vibrator. A thickness of the first member is equal to or more than a thickness of the second member.

In the vibration device according to Aspect 1, the first member and the second member function as cushioning layers that reduce the thermal stresses caused by differences between the coefficients of linear expansion of the members that are the light-transmitting element, the vibrator, and the holding portion. This enables improvement in the reliability of joining between the light-transmitting element and the vibrator and between the light-transmitting element and the holding portion.

In the vibration device according to Aspect 2 of the present disclosure, in Aspect 1, a Young's modulus of the first member is equal to or less than a Young's modulus of the second member.

The vibration device according to Aspect 2 is capable of more certainly improving the reliability of joining between the light-transmitting element and the vibrator and between the light-transmitting element and the holding portion.

In the vibration device according to Aspect 3 of the present disclosure, in Aspect 1 or 2, the second member contains an adhesive material.

The vibration device according to Aspect 3 is capable of more certainly inhibiting a reduction of vibrations of the vibration device.

In the vibration device according to Aspect 4 of the present disclosure, in any one of Aspects 1 to 3, the first member contains a waterproof material.

The vibration device according to Aspect 4 is capable of more certainly inhibiting droplets from entering the vibration device.

A vibration device according to Aspect 5 of the present disclosure includes: a vibrator; a piezoelectric element located at one end of the vibrator in a first direction; a light-transmitting element located at another end of the vibrator in the first direction; a holding portion that holds, along with the other end of the vibrator, the light-transmitting element in the first direction; a first member that is located between the light-transmitting element and the holding portion and that is connected to the light-transmitting element and the holding portion; and a second member that is located between the light-transmitting element and the vibrator and that is connected to the light-transmitting element and the vibrator. A Young's modulus of the first member is equal to or less than a Young's modulus of the second member.

In the vibration device according to Aspect 5, the first member and the second member function as cushioning layers that reduce the thermal stresses caused by differences between the coefficients of linear expansion of the members that are the light-transmitting element, the vibrator, and the holding portion. This enables improvement in the reliability of joining between the light-transmitting element and the vibrator and between the light-transmitting element and the holding portion.

In the vibration device according to Aspect 6 of the present disclosure, in Aspect 5, a thickness of the first member is equal to or more than a thickness of the second member.

The vibration device according to Aspect 6 is capable of more certainly improving the reliability of joining between the light-transmitting element and the vibrator and between the light-transmitting element and the holding portion.

In the vibration device according to Aspect 7 of the present disclosure, in Aspect 5 or 6, the second member contains an adhesive material.

The vibration device according to Aspect 7 is capable of more certainly inhibiting a reduction of vibrations of the vibration device.

In the vibration device according to Aspect 8 of the present disclosure, in any one of Aspects 5 to 7, the first member contains a waterproof material.

The vibration device according to Aspect 8 is capable of more certainly inhibiting droplets from entering the vibration device.

The vibration device according to Aspect 9 of the present disclosure, in any one of Aspects 1 to 8, further includes: an outer vibrator; and a stopper portion. The outer vibrator includes a first connection portion that includes the holding portion and that is connected to the light-transmitting element via the holding portion, a second connection portion extending from the first connection portion in a direction away from the light-transmitting element along a direction crossing the first direction, and a fixing portion connected to an end portion opposite to an end portion connected to the first connection portion of two end portions of the second connection portion in the direction crossing the first direction. The stopper portion is connected to the fixing portion in a state in which the second connection portion is able to come into contact with the stopper portion. A first space is provided between the stopper portion and the second connection portion in the first direction.

In the vibration device according to Aspect 9, for example, when an external force is applied to the light-transmitting element toward the inside of the vibration device, the second connection portion comes into contact with the stopper portion. Thus, it is possible to prevent the light-transmitting element from coming into contact with the members located inside the vibration device. In addition, for example, when a stress is applied to the second connection portion, the second connection portion comes into contact with the stopper portion. Thus, it is possible to prevent the second connection portion from being excessively deformed.

In the vibration device according to Aspect 10 of the present disclosure, in Aspect 9, the stopper portion has an inclined surface facing the second connection portion in the first direction, and the inclined surface is inclined so as to be away from the second connection portion in the first direction toward the first connection portion in the direction crossing the first direction.

The vibration device according to Aspect 10 is capable of more certainly preventing the light-transmitting element from coming into contact with the members located inside the vibration device and of more certainly preventing the second connection portion from being excessively deformed.

In the vibration device according to Aspect 11 of the present disclosure, in Aspect 9 or 10, the fixing portion is formed so as to surround the vibrator around an optical axis of the light-transmitting element, and the stopper portion has an annular shape extending in a circumferential direction around the optical axis.

The vibration device according to Aspect 11 is capable of more certainly preventing the light-transmitting element from coming into contact with the members located inside the vibration device and of more certainly preventing the second connection portion from being excessively deformed.

In the vibration device according to Aspect 12 of the present disclosure, in Aspect 9 or 10, the fixing portion is formed so as to surround the vibrator around an optical axis of the light-transmitting element, and the stopper portion includes a plurality of members located spaced from each other in a circumferential direction around the optical axis.

The vibration device according to Aspect 12 is capable of more certainly preventing the light-transmitting element from coming into contact with the members located inside the vibration device and of more certainly preventing the second connection portion from being excessively deformed.

In the vibration device according to Aspect 13 of the present disclosure, in any one of Aspects 9 to 12, the fixing portion and the stopper portion are integrally formed with each other.

The vibration device according to Aspect 13 eliminates the need for connection of the stopper portion to the fixing portion. Thus, it is possible to reduce the manufacturing cost of the vibration device.

In the vibration device according to Aspect 14 of the present disclosure, in any one of Aspects 9 to 13, the fixing portion has a first facing surface facing and spaced from the second connection portion in the first direction, and the stopper portion is connected to the first facing surface.

The vibration device according to Aspect 14 is capable of more certainly preventing the light-transmitting element from coming into contact with the members located inside the vibration device and of more certainly preventing the second connection portion from being excessively deformed.

In the vibration device according to Aspect 15 of the present disclosure, in any one of Aspects 9 to 13, the fixing portion has a second facing surface facing and spaced from the vibrator in the direction crossing the first direction, and the stopper portion is connected to the second facing surface.

In the vibration device according to Aspect 15, it is possible to adjust the size of the first space according to, for example, the structure of the vibration device and the material of each member forming the vibration device.

In the vibration device according to Aspect 16 of the present disclosure, in any one of Aspects 9 to 15, the stopper portion includes a first layer and a second layer laminated in the first direction, and the first layer is located closer to the second connection portion than the second layer and is formed so as to have a lower elastic modulus than the second layer.

In the vibration device according to Aspect 16, the deformation of the second connection portion that has come into contact with the stopper portion slows down. Thus, it is possible to more certainly prevent the second connection portion from being excessively deformed. In addition, it is possible to prevent the second connection portion from being damaged when the second connection portion comes into contact with the stopper portion.

In the vibration device according to Aspect 17 of the present disclosure, in any one of Aspects 9 to 16, the first space has a size equal to or larger than a maximum amplitude of the light-transmitting element and smaller than the second space.

The vibration device according to Aspect 17 is capable of more certainly preventing the light-transmitting element from coming into contact with the members located inside the vibration device and of more certainly preventing the second connection portion from being excessively deformed.

An embodiment of the present disclosure will be described below with reference to drawings. The following description is not intended to limit the present disclosure, is essentially merely an example, and can be modified as appropriate without departing from the gist of the present disclosure. The drawings are schematic, and, for example, size ratios therein do not necessarily coincide with actual ones.

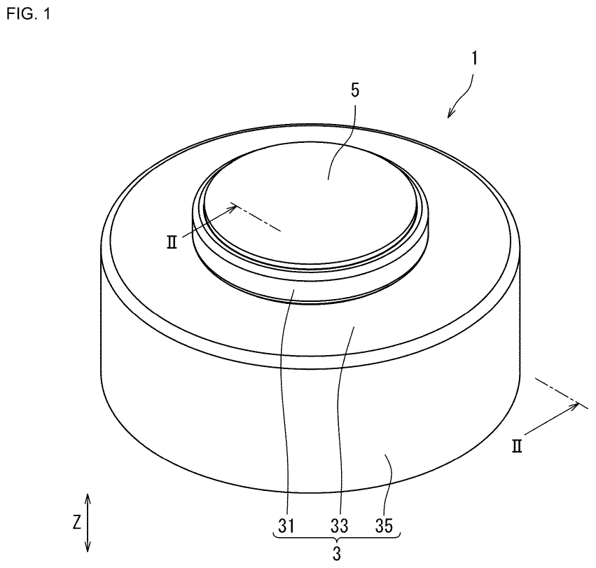

As illustrated in FIGS. 1 to 4, a vibration device 1 in an embodiment of the present disclosure includes a lens 5 (an example of a light-transmitting element), an inner vibrator 7 (an example of a vibrator), a piezoelectric element 9, a holding portion 31b, a first member 40, and a second member 50.

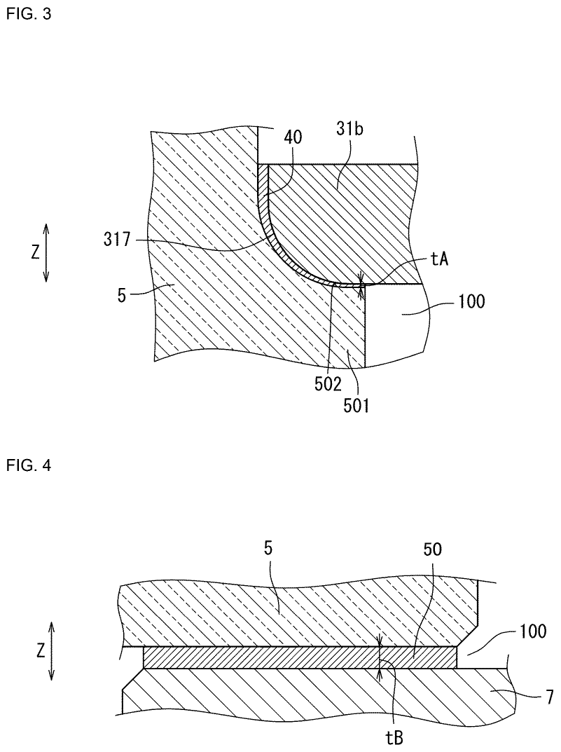

For example, the lens 5 is made of glass. As illustrated in FIG. 1, an upper surface of the lens 5 has a convex shape and has a water-repellent coating and an antireflection coating (AR coating). A projection 501 extending outward in radial directions is provided at the outer end of the lens 5 in the radial directions. An upper surface 502 (see FIG. 3) of the projection 501 curves along a curved surface 317 of the holding portion 31b described later.

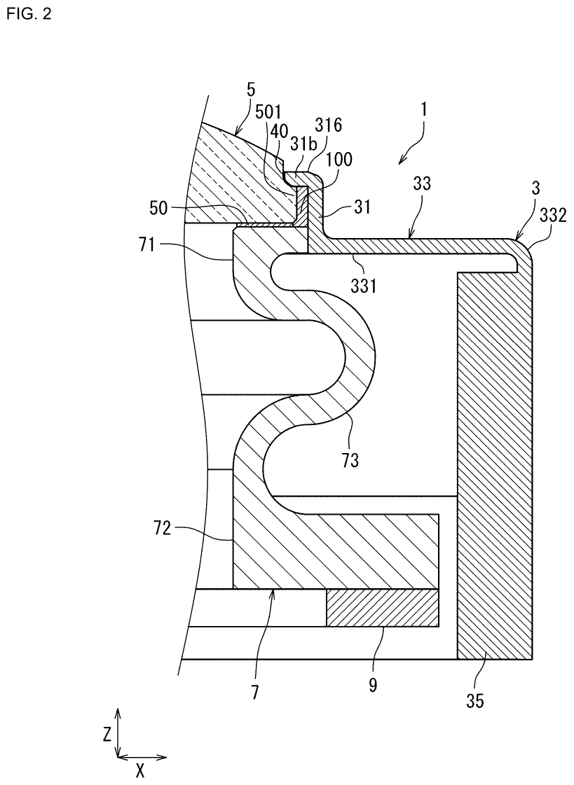

For example, the inner vibrator 7 includes a tubular body and amplifies vibrations from the piezoelectric element 9 to vibrate the lens 5. In the present embodiment, as illustrated in FIG. 2, the inner vibrator 7 is formed by a first portion 71, which is adjacent to the lens 5, a second portion 72, to which the piezoelectric element 9 is attached, and a third portion 73, which connects the first portion 71 and the second portion 72 and has a substantially S-shaped sectional shape. The first portion 71 has a cylindrical shape extending in the axial direction (for example, a first direction Z) of the tubular body. The first portion 71 extends in the radial directions of the tubular body and is connected to an outer vibrator 3. The second portion 72 is a portion configured to vibrate along with vibrations of the piezoelectric element 9 and has a larger thickness than the first portion 71 and the third portion 73. This facilitates more efficient transmission of vibrations of the piezoelectric element 9 to the lens 5. The third portion 73 is a portion supporting the first portion 71 and configured to transmit vibrations of the second portion 72 to the first portion 71. The second portion 72 forms one end of the inner vibrator 7 in the first direction Z. The first portion 71 forms the other end of the inner vibrator 7 in the first direction Z.

The first portion 71, the second portion 72, and the third portion 73 may be formed integrally with each other or separately from each other. As illustrated in FIG. 2, the maximum external dimension (maximum dimension in the X direction) of the third portion 73 is larger than the maximum external dimension of the first portion 71, and the maximum external dimension of the second portion 72 is larger than the maximum external dimension of the third portion 73. This enables efficient transmission of vibrations of the piezoelectric element 9 to the lens 5.

The piezoelectric element 9 includes a piezoelectric body and an electrode. For example, the piezoelectric body contains piezoelectric ceramics such as barium titanate (BaTiO₃), lead zirconate titanate (PZT: PbTiO₃·PbZrO₃), lead titanate (PbTiO₃), lead metaniobate (PbNb₂O₆), bismuth titanate (Bi₄Ti₃O₁₂), or (K,Na)NbO₃, or a piezoelectric single crystal of, for example, LiTaO₃ or LiNbO₃. The electrode may be, for example, a Ni electrode. The electrode may be an electrode formed, through sputtering, by a thin film made of metal such as Ag or Au. Alternatively, the electrode can be formed through plating or vapor deposition besides sputtering.

In the present embodiment, the piezoelectric element 9 is connected to the second portion 72 of the inner vibrator 7 with an adhesive. The piezoelectric element 9 has a ring shape when viewed in the first direction Z. However, the shape of the piezoelectric element 9 is not limited thereto, and it is sufficient that the piezoelectric element 9 be shaped so as to be able to vibrate the inner vibrator 7.

The holding portion 31b forms a part of the outer vibrator 3. As illustrated in FIG. 1, the outer vibrator 3 includes a fixing portion 35, a first connection portion 31, and a second connection portion 33. The holding portion 31b is configured to be able to hold, along with the first portion 71 of the inner vibrator 7, the projection 501 of the lens 5. In the present embodiment, the first connection portion 31 is located outside the first portion 71 of the inner vibrator 7 and the lens 5 in the radial directions and extends from the second connection portion 33 toward the outside of the vibration device 1 in the first direction Z. The holding portion 31b projects toward the lens 5 from the end of the first connection portion 31 farther from the second connection portion 33 in the first direction Z. The curved surface 317 (see FIG. 3) projecting toward the lens 5 is provided at the end (that is, the end facing the lens 5) of the holding portion 31b. That is, the holding portion 31b is provided to the first connection portion 31. The first connection portion 31 is connected to the lens 5 via the holding portion 31b.

The second connection portion 33 extends from the first connection portion 31 in a direction away from the lens 5 along a direction crossing the first direction Z (for example, the X direction). In the present embodiment, the second connection portion 33 extends annularly in directions perpendicular to the optical axis direction (for example, the first direction Z) of the lens 5 (in other words, the radial directions relative to the optical axis direction). The thickness of the second connection portion 33 is smaller than the thickness of the fixing portion 35 and is, for example, 0.2 mm to 1.0 mm. In addition, the thickness of the second connection portion 33 is, for example, 0.2 times to 1.5 times of that of the third portion 73 of the inner vibrator 7. The second connection portion 33 has such a thin thickness and thus functions as a flat spring. In the present embodiment, the second connection portion 33 is configured to be able to elastically deform in the first direction Z so as to absorb vibrations generated in the lens 5.

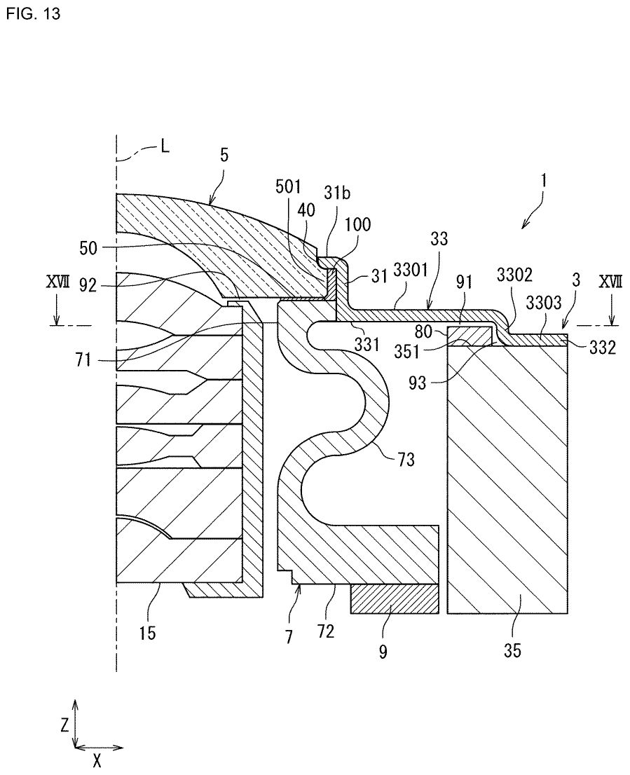

Of two end portions of the second connection portion 33 in the direction crossing the first direction Z, the fixing portion 35 is connected to an end portion 332 opposite to an end portion 331 connected to the first connection portion 31. The fixing portion 35 is connected to members such as a case (not illustrated) housing an imaging element and a lens module 15 (see FIG. 13), has nodes that reduce vibrations to vibrations having a displacement amount equal to or less than one hundredth of the displacement amount of the lens 5, and is configured not to propagate vibrations to these members. Vibrations of the fixing portion 35 can be reduced as the volume of the fixing portion 35 increases. In the present embodiment, the fixing portion 35 has an external shape that is quadrilateral. When the external shape is quadrilateral, the volume of the fixing portion 35 can be increased without increasing the size of the vibration device 1. For example, the volume of a cube having a size of 25 mm×25 mm is larger than the volume of a cylinder having a diameter of 25 mm.

In the vibration device 1, an elastic body such as rubber or an adhesive layer is provided to a portion 100 surrounded by the lens 5, the first connection portion 31 of the outer vibrator 3, and the first portion 71 of the inner vibrator 7. This reduces the load on the lens 5.

As illustrated in FIG. 3, the first member 40 is located between the lens 5 and the holding portion 31b and is connected to the lens 5 and the holding portion 31b. As illustrated in FIG. 4, the second member 50 is located between the lens 5 and the inner vibrator 7 and is connected to the lens 5 and the inner vibrator 7. The first member 40 and the second member 50 contain a material such as resin or metal and are configured to satisfy at least one of the following two conditions.
A thickness tA of the first member 40 is equal to or more than a thickness tB of the second member 50 (tA≥tB).
A Young's modulus yA of the first member 40 is equal to or less than a Young's modulus yB of the second member 50 (yA≤yB).

The thickness tA of the first member 40 is defined at a portion where the thickness of the first member 40 is smallest. The thickness tB of the second member 50 is substantially uniform due to the flatness of the joint between the lens 5 and the inner vibrator 7 and may thus be defined at any portion of the second member 50.

When the first member 40 and the second member 50 are made of a liquid adhesive, for example, the thickness tA of the first member 40 and the thickness tB of the second member 50 can be controlled by using, for example, the viscosity of the adhesive, the amount of pressure when the adhesive is solidified, or the diameter of a spacer added to the adhesive. For example, the thickness tA of the first member 40 and the thickness tB of the second member 50 can be confirmed by observing a section of the vibration device 1 with a microscope.

Amplifying fine breathing vibrations of the piezoelectric element 9 in, for example, the inner vibrator 7 and the holding portion 31b to transmit the vibrations to the lens 5 is the point to maximize vibrations of the lens 5. The first member 40 and the second member 50 have mainly two roles that are “transmission of vibrations” and “improvement in the reliability of joining between different kinds of materials”. Since the Young's modulus of the first member 40 and the Young's modulus of the second member 50 are low, the first member 40 and the second member 50 having thinner thicknesses are advantageous to “transmission of vibrations”. In consideration of functioning as cushioning layers that reduce the thermal stresses caused by differences between the coefficients of linear expansion of the members that are the lens 5, the inner vibrator 7, and the holding portion 31b, the first member 40 and the second member 50 having comparatively thick thicknesses are advantageous to “improvement in the reliability of joining between different kinds of materials”. However, it has been found that the thickness sensitivity of vibration characteristics and thermal stress varies among portions of the first member 40 and the second member 50. That is, when the relationship of the thickness sensitivity is clarified, it is possible to select a relationship advantageous to both of “transmission of vibrations” and “improvement in the reliability of joining between different kinds of materials” by control of the thickness of each of the portions of the first member 40 and the second member 50.

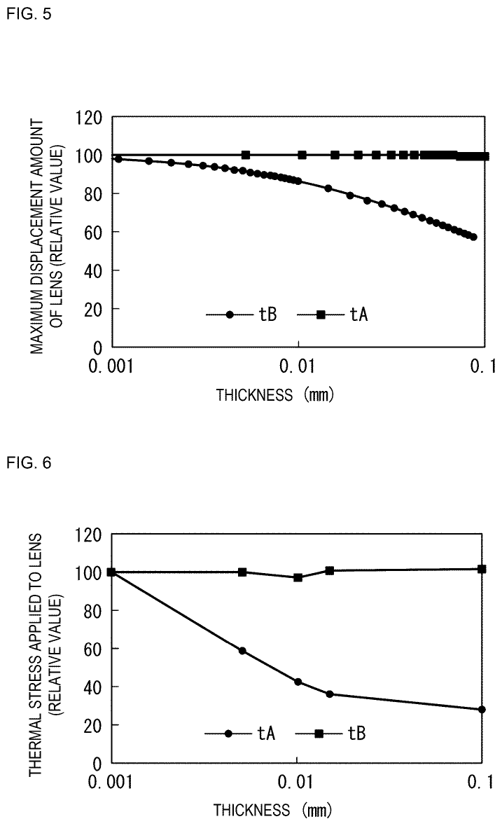

FIG. 5 is a graph illustrating the relationship between the respective thicknesses tA and tB of the first member 40 and the second member 50 and the maximum displacement amount of a top portion of the lens 5 and made by using a finite element method (FEM). The physical property constants used for the FEM calculation results are given in Table 1 below.

TABLE 1

| | | Coefficient of | |
|---|---|---|---|
| | | Linear | Young's |
| | | Expansion | Modulus |
| | Material | (×10⁻⁵1/deg) | (Gpa) |
| Lens 5 | Glass | 0.6 | 125 |
| Holding | SUS420J2 | 1.03 | 200 |
| Portion 31b | | | |
| First Member | Epoxy Resin | 2.0 | 3 |
| 40 and Second | | | |
| Member 50 | | | |

The displacement amount of the top portion of the lens 5 is a relative value when 0.001 mm (tA and tB) is 100. When one of the thicknesses of the first member 40 and the second member 50 is changed, the other of the thicknesses of the first member 40 and the second member 50 is fixed at 0.005 mm. As a result, in the sensitivity of the displacement amount of the top portion of the lens 5 to the thicknesses of the first member 40 and the second member 50, the second member 50 (tB) has higher sensitivity. It has thus been found that the displacement amount of the top portion of the lens 5 is reduced as the thickness of the second member 50 increases. This is due to the following reason. As vibrations caused by a fine displacement generated in the piezoelectric element 9 are amplified through the piezoelectric element 9, the inner vibrator 7, the second member 50, and the lens 5, the stress applied to the second member 50 increases, and the second member 50 thus becomes easily deformed. Epoxy resin, which is the material for the first member 40 and the second member 50, is a material having a comparatively low Young's modulus and thus has an effect of reducing vibrations by the deformation thereof. That is, when the thickness tA of the first member 40, which is configured to be slightly deformed and slightly contributes to propagation of vibrations to the lens 5, increases, the displacement amount of the top portion of the lens 5 is slightly reduced, whereas when the thickness tB of the second member 50, which is configured to be greatly deformed, increases, the displacement amount of the top portion of the lens 5 is greatly reduced.

On the other hand, in terms of “improvement in the reliability of joining between different kinds of materials”, the thicknesses tA and tB of the first member 40 and the second member 50 function differently from the above. The following description particularly focuses on a stress that is a thermal stress generated by a thermal load instead of vibrations. A larger thermal stress is applied to a joint between different kinds of materials as the difference between coefficients of linear expansion peculiar to materials increases, thus causing, for example, peeling of the first member 40 and the second member 50 or member damage. For example, as shown in Table 1 above, the coefficient of linear expansion of the lens 5 (glass), which is 0.6×10⁻⁵(1/deg), and the coefficient of linear expansion of the holding portion 31b (stainless steel), which is 1.03×10⁻⁵(1/deg) differ from each other. When a combination of materials in which the difference between the coefficients of linear expansion is larger is selected, the thermal stress applied to the members that are the lens 5, the inner vibrator 7, and the holding portion 31b increases.

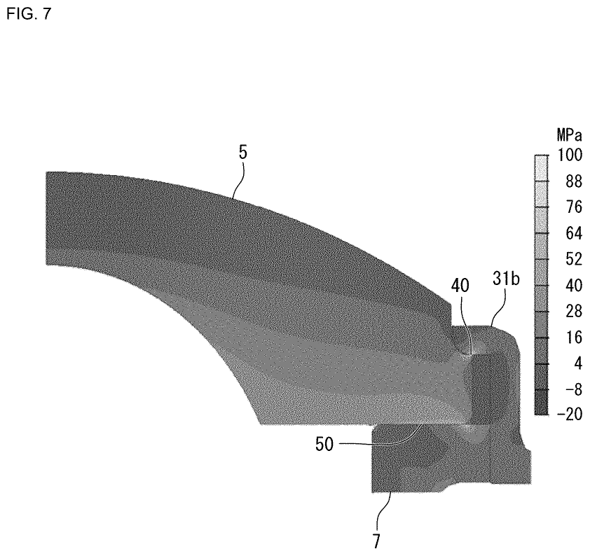

FIG. 6 is a graph illustrating the relationship between the respective thicknesses tA and tB of the first member 40 and the second member 50 and the maximum thermal stress applied to the lens 5 and made by using the FEM. The physical property constants used for the FEM calculation results are given in Table 1 above. The thermal stress is a relative value when 0.001 mm (tA and tB) is 100. When one of the thicknesses of the first member 40 and the second member 50 is changed, the other of the thicknesses of the first member 40 and the second member 50 is fixed at 0.005 mm. As a result, in the sensitivity of the thermal stress to the thicknesses tA and tB of the first member 40 and the second member 50, the first member 40 (tA) has higher sensitivity. It has thus been found that the thermal stress is greatly reduced as the thickness of the first member 40 increases. On the other hand, the thermal stress is changed little as the thickness of the second member 50 (tB) increases. This is because the portion to which a large thermal stress is applied is in the vicinity of the holding portion 31b (see FIG. 7).

As described above, it has been found that the effective relationship between tA and tB is “tA≥tB” in terms of “transmission of vibrations” and “improvement in the reliability of joining between different kinds of materials”. This relationship holds regardless of the shape of the lens 5.

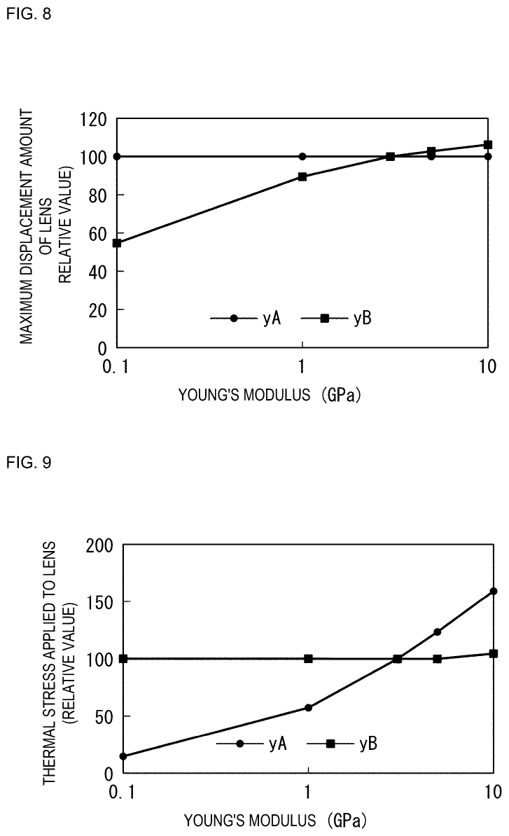

FIG. 8 is a graph illustrating the relationship between the respective Young's moduli yA and yB of the first member 40 and the second member 50 and the maximum displacement amount of the top portion of the lens 5 and made by using the FEM. The physical property constants used for the FEM calculation results are given in Table 1 above. The maximum displacement amount of the top portion of the lens 5 is a relative value when 3 GPa (yA and yB) is 100. When one of the Young's moduli of the first member 40 and the second member 50 is changed, the other of the Young's moduli of the first member 40 and the second member 50 is fixed at 3 GPa. As a result, in the sensitivity of the displacement amount of the top portion of the lens 5 to the Young's moduli yA and yB of the first member 40 and the second member 50, the second member 50 (yB) has higher sensitivity. It has thus been found that the displacement amount of the top portion of the lens 5 increases as the Young's modulus increases. On the other hand, the first member 40 (yA) has little sensitivity of the displacement amount of the top portion of the lens 5 to a change of the Young's modulus.

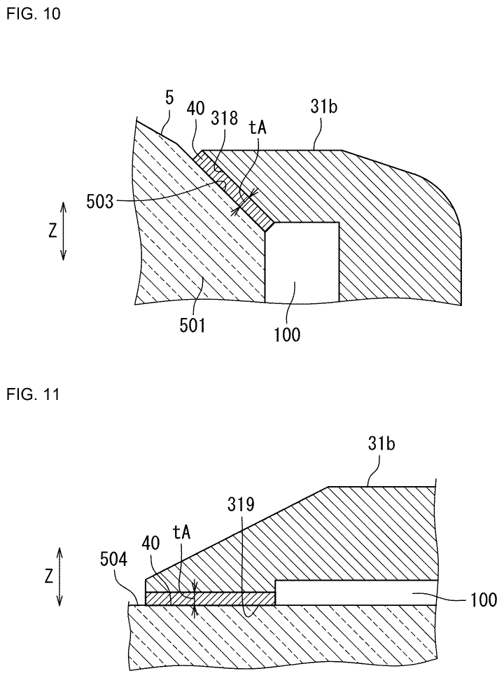

FIG. 9 is a graph illustrating the relationship between the respective Young's moduli yA and yB of the first member 40 and the second member 50 and the maximum thermal stress applied to the lens 5 and made by using the FEM. The physical property constants used for the FEM calculation results are given in Table 1 above. The thermal stress is a relative value when 3 GPa (yA and yB) is 100. When one of the Young's moduli of the first member 40 and the second member 50 is changed, the other of the Young's moduli of the first member 40 and the second member 50 is fixed at 3 GPa. As a result, in the sensitivity of the thermal stress to the Young's moduli, the first member 40 (yA) has higher sensitivity. It has thus been found that the thermal stress is greatly reduced as the Young's modulus is reduced. On the other hand, the second member 50 (yB) has little sensitivity of the thermal stress to the Young's modulus.

As described above, it has been found that the effective relationship between yA and yB is “yA≤yB” in terms of “transmission of vibrations” and “improvement in the reliability of joining between different kinds of materials”. This relationship holds regardless of the kind of material used for the first member 40 and the second member 50. That is, the first member 40 and the second member 50 may be made of the same material or different materials.

The vibration device 1 of the present disclosure includes the inner vibrator 7, the piezoelectric element 9, which is located at one end of the inner vibrator 7 in the first direction, the lens 5, which is located at the other end of the inner vibrator 7 in the first direction, the holding portion 31b, which holds, along with the other end of the inner vibrator 7, the lens 5 in the first direction, the first member 40, and the second member 50. The first member 40 is located between the lens 5 and the holding portion 31b and is connected to the lens 5 and the holding portion 31b. The second member 50 is located between the lens 5 and the inner vibrator 7 and is connected to the lens 5 and the inner vibrator 7. The first member 40 and the second member 50 are configured to satisfy at least one of the following conditions. Such a configuration enables improvement in the reliability of joining between the lens 5 and the inner vibrator 7 and between the lens 5 and the holding portion 31b.
The thickness tA of the first member 40 is equal to or more than the thickness tB of the second member 50 (tA≥tB).
The Young's modulus yA of the first member 40 is equal to or less than the Young's modulus yB of the second member 50 (yA≤yB).

The vibration device 1 can also be configured as follows.

The first member 40 may contain a waterproof material. This can more certainly inhibit droplets from entering the vibration device 1. Examples of such a waterproof material include a material satisfying an IP test of IPX9K in accordance with an in-vehicle and automotive component standard: ISO 20653.

The second member 50 may contain an adhesive material. This ensures the vibration characteristics of the vibration device 1 and can thus more certainly inhibit a reduction of vibrations of the vibration device 1. Examples of such an adhesive material include an adhesive having a tensile strength between the lens 5 and the inner vibrator 7 more than a shearing stress or a Z vertical stress applied during driving of the vibration device 1.

The respective shapes of the lens 5 and the holding portion 31b are not limited to those in the embodiment. For example, as illustrated in FIG. 10, an inclined surface 318 extending linearly may be provided to the end of the holding portion 31b, and an inclined surface 503 facing the inclined surface 318 may be provided to an upper surface of the projection 501 of the lens 5. As illustrated in FIG. 11, a flat upper surface 504 may be provided to the lens 5, and a holding surface 319 facing the upper surface 504 of the lens 5 may be provided to the end of the holding portion 31b.

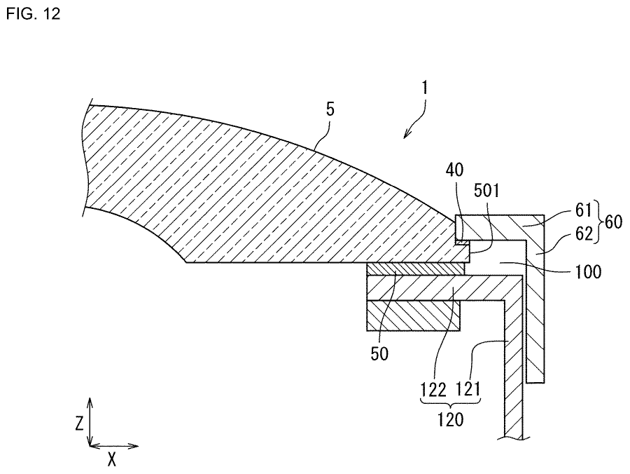

The holding portion is not limited to the case of the holding portion 31b forming a part of the vibrator (the outer vibrator 3 in the embodiment). For example, as illustrated in FIG. 12, the holding portion may be formed by a member (also referred to as a holding member) 60 different from the vibrator. In the vibration device 1 in FIG. 12, for example, the holding member 60 includes a side wall 62, which has a cylindrical shape, and a pressing portion 61, which projects inward (for example, in the X direction and a direction toward the lens 5) in radial directions relative to the optical axis of the side wall 62 (hereinafter referred to as radial directions). For example, a vibrator 120 includes a main body portion 121, which has a cylindrical shape, and a support portion 122, which projects inward in the radial directions from the main body portion 121.

As illustrated in FIGS. 13 to 16, the vibration device 1 may include a stopper portion 80. The stopper portion 80 is connected to the fixing portion 35 in a state in which the second connection portion 33 is able to come into contact with the stopper portion 80. A first space 91 is provided between the stopper portion 80 and the second connection portion 33 in the first direction Z. The stopper portion 80 can be made of a material such as metal or resin.

In the vibration device 1 illustrated in FIG. 13, the fixing portion 35 has a first facing surface 351 facing and spaced from the second connection portion 33 in the first direction Z. The stopper portion 80 is connected to the first facing surface 351 of the fixing portion 35. In the vibration device 1 illustrated in FIG. 13, the stopper portion 80 is a member different from the fixing portion 35 and is fixed to the fixing portion 35 with an adhesive, for example.

The second connection portion 33 is formed by a first flat spring portion 3301, a second flat spring portion 3302, and a coupling portion 3303. The first flat spring portion 3301 extends outward in the radial directions from the end portion 331 connected to the first connection portion 31. The stopper portion 80 is located between the first flat spring portion 3301 and the first facing surface 351. The second flat spring portion 3302 extends toward the fixing portion 35 in the first direction Z from the end portion farther from the first connection portion 31 of two end portions of the first flat spring portion 3301 in the radial directions. A third space 93 is provided between the fixing portion 35 and the second flat spring portion 3302. The third space 93 does not have to be provided. The coupling portion 3303 extends outward in the radial directions along the first facing surface 351 from the end portion closer to the fixing portion 35 of two end portions of the second flat spring portion 3302 in the first direction Z. The end portion of the coupling portion 3303 located outside in the radial directions forms the end portion 332. The second connection portion 33 is connected to the fixing portion 35 via the coupling portion 3303.

For example, when an external force is applied to the lens 5 toward the inside of the vibration device 1, the second connection portion 33 moves toward the inside of the vibration device 1 via the first connection portion 31 connected to the lens 5 and comes into contact with the stopper portion 80. The contact of the second connection portion 33 with the stopper portion 80 restrains the second connection portion 33 from moving toward the inside of the vibration device 1 and as a result restrains the lens 5 from moving toward the inside of the vibration device 1. That is, the provision of the stopper portion 80 can prevent the lens 5 from coming into contact with the members (for example, the lens module 15) located inside the vibration device 1. In addition, for example, when a stress is applied to the second connection portion 33, the second connection portion 33 comes into contact with the stopper portion 80, thus enabling the second connection portion 33 to be prevented from being excessively deformed.

In the vibration device 1 illustrated in FIG. 13, the stopper portion 80 is connected to the first facing surface 351 of the fixing portion 35. Thus, it is possible to more certainly prevent the lens 5 from coming into contact with the members (for example, the lens module 15) located inside the vibration device 1 and to more certainly prevent the second connection portion 33 from being excessively deformed.

For example, the first space 91 has a size equal to or larger than the maximum amplitude of the lens 5 and smaller than a second space 92. With such a configuration, it is possible to more certainly prevent the lens 5 from coming into contact with the members (for example, the lens module 15) located inside the vibration device 1 and to more certainly prevent the second connection portion 33 from being excessively deformed. For example, the second space 92 is the minimum space of the spaces between the lens 5 and the lens module 15 in the first direction Z.

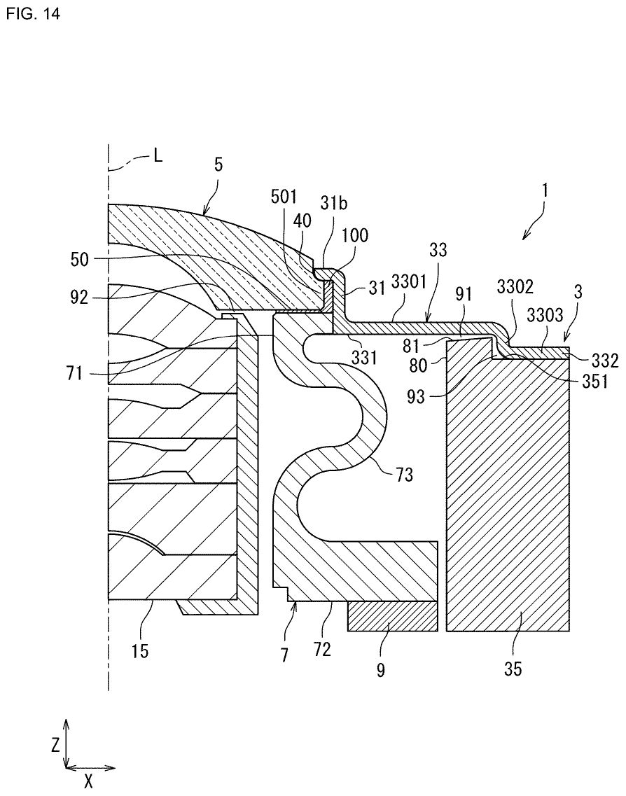

In the vibration device 1 illustrated in FIG. 14, the fixing portion 35 and the stopper portion 80 are integrally formed with each other. The integral formation of the fixing portion 35 and the stopper portion 80 eliminates the need for connection of the stopper portion 80 to the fixing portion 35, thus enabling a reduction in the manufacturing cost of the vibration device 1.

In the vibration device 1 illustrated in FIG. 14, the stopper portion 80 has an inclined surface 81 facing the second connection portion 33 in the first direction Z. The inclined surface 81 is inclined so as to be away from the second connection portion 33 in the first direction Z toward the first connection portion 31 in the direction crossing the first direction Z (for example, the X direction). Compared with the vibration device 1 including the stopper portion 80 without the inclined surface 81, the provision of the inclined surface 81 can increase the area where the stopper portion 80 and the first flat spring portion 3301 of the second connection portion 33 are able to come into contact with each other. As a result, it is possible to more certainly prevent the lens 5 from coming into contact with the members (for example, the lens module 15) located inside the vibration device 1 and to more certainly prevent the second connection portion 33 from being excessively deformed.

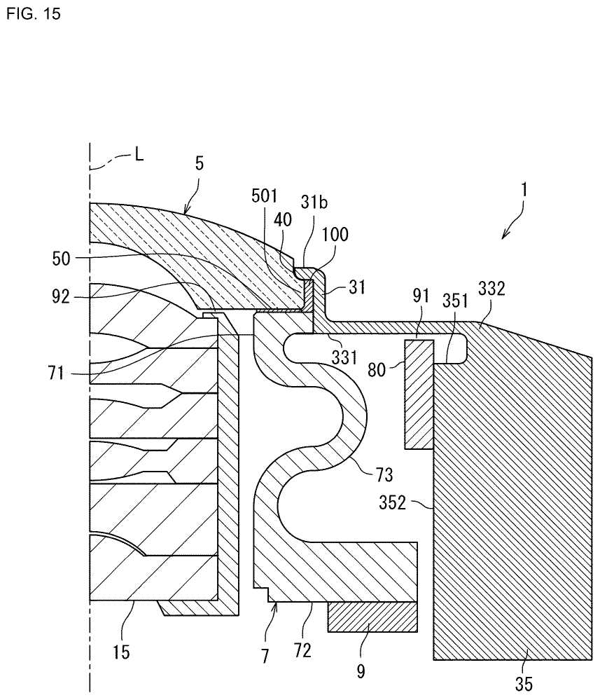

In the vibration device 1 illustrated in FIG. 15, the fixing portion 35 has a second facing surface 352 facing and spaced from the inner vibrator 7 in the direction crossing the first direction Z (for example, the X direction). The stopper portion 80 is connected to the second facing surface 352 of the fixing portion 35. In the vibration device 1 illustrated in FIG. 15, the stopper portion 80 is a member different from the fixing portion 35 and is fixed to the fixing portion 35 with an adhesive, for example. The provision of the stopper portion 80 on the second facing surface 352 can adjust the size of the first space 91 according to, for example, the structure of the vibration device 1 and the material of each member forming the vibration device 1.

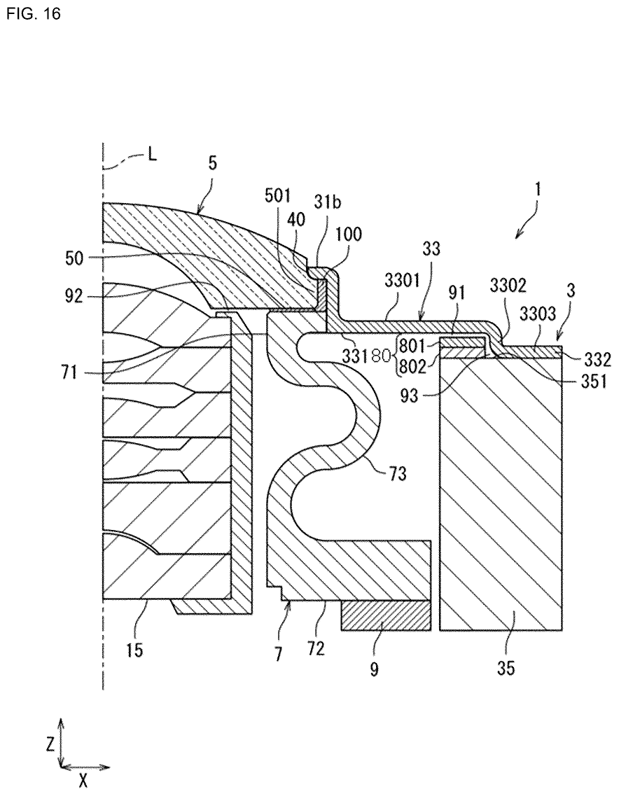

In the vibration device 1 illustrated in FIG. 16, the stopper portion 80 includes a first layer 801 and a second layer 802 laminated in the first direction Z. The first layer 801 is located closer to the second connection portion 33 than the second layer 802. That is, the first space 91 is formed between the first layer 801 and the first flat spring portion 3301. The first layer 801 is formed so as to have a lower elastic modulus than the second layer 802. Such a configuration slows down the deformation of the second connection portion 33 that has come into contact with the stopper portion 80. Thus, it is possible to more certainly prevent the second connection portion 33 from being excessively deformed. In addition, it is possible to prevent the second connection portion 33 from being damaged when the second connection portion 33 comes into contact with the stopper portion 80.

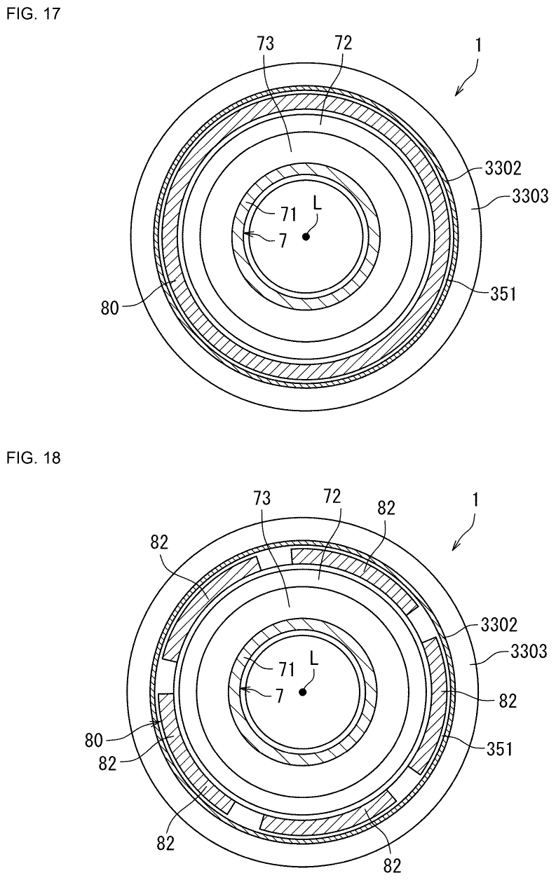

For example, as illustrated in FIG. 17, the stopper portion 80 can be formed so as to have an annular shape extending in a circumferential direction around an optical axis L of the lens 5. In this case, the fixing portion 35 is formed so as to surround the inner vibrator 7 around the optical axis L. The stopper portion 80 is not limited to having such an annular shape and, for example, as illustrated in FIG. 18, may be formed so as to include a plurality of members 82 located spaced from each other in a circumferential direction around the optical axis L. All or some of the plurality of members 82 may have substantially the same shape and size. All of the plurality of members 82 may have respective different shapes and sizes. With such a configuration, it is possible to more certainly prevent the lens 5 from coming into contact with the members (for example, the lens module 15) located inside the vibration device 1 and to more certainly prevent the second connection portion 33 from being excessively deformed.

Freely selected embodiments and/or modification examples of the various embodiments and modification examples of the present disclosure can be combined as appropriate. Combinations of the embodiments and/or the modification examples include combinations of the configurations of the embodiments and/or the configurations of modification examples.

The present disclosure is fully described through the embodiments and/or the modification examples with reference to the accompanying drawings. However, the embodiments and/or the modification examples do not cover the entire present disclosure. Those skilled in the technical field of the present disclosure can make a number of alterations and modifications. It should be understood that such alterations and modifications are included in the present disclosure without departing from the scope of the present disclosure.

### Reference Signs List

1 vibration device
3 outer vibrator
5 lens
7 inner vibrator
9 piezoelectric element
15 lens module
31 first connection portion
31b holding portion
33 second connection portion
3301 first flat spring portion
3302 second flat spring portion
3303 coupling portion
331, 332 end portion
35 fixing portion
351 first facing surface
352 second facing surface
40 first member
50 second member
60 holding member
61 pressing portion
62 side wall
71 first portion
72 second portion
73 third portion
80 stopper portion
81 inclined surface
82 plurality of members
801 first layer
802 second layer
91 first space
92 second space
93 third space
100 portion
120 vibrator
121 main body portion
122 support portion
317 curved surface
318 inclined surface
319 holding surface
501 projection
502 upper surface
503 inclined surface
504 upper surface

1. A vibration device comprising:
a vibrator;
a piezoelectric element at a first end of the vibrator in a first direction;
a light-transmitting element at a second end of the vibrator in the first direction;
a holding portion that holds the second end of the vibrator and the light-transmitting element in the first direction;
a first member between the light-transmitting element and the holding portion and connected to the light-transmitting element and the holding portion; and
a second member between the light-transmitting element and the vibrator and connected to the light-transmitting element and the vibrator,
wherein a thickness of the first member is equal to or more than a thickness of the second member.

2. The vibration device according to claim 1, wherein a Young's modulus of the first member is equal to or less than a Young's modulus of the second member.

3. The vibration device according to claim 1, wherein the second member contains an adhesive material.

4. The vibration device according to claim 1, wherein the first member contains a waterproof material.

5. The vibration device according to claim 1, further comprising:
an outer vibrator, wherein the outer vibrator includes:
a first connection portion that includes the holding portion and is connected to the light-transmitting element via the holding portion,
a second connection portion extending from the first connection portion in a direction away from the light-transmitting element along a direction crossing the first direction, and
a fixing portion connected the second connection portion on an end thereof opposite to the first connection portion; and
a stopper portion connected to the fixing portion in a state in which the second connection portion is able to come into contact with the stopper portion and a first space is defined between the stopper portion and the second connection portion in the first direction.

6. The vibration device according to claim 5, wherein
the stopper portion has an inclined surface facing the second connection portion in the first direction, and
the inclined surface is inclined away from the second connection portion in the first direction toward the first connection portion in the direction crossing the first direction.

7. The vibration device according to claim 5, further comprising:
a lens module inside the vibrator and defining a second space between the light-transmitting element and the lens module,
wherein the first space has a size equal to or larger than a maximum amplitude of the light-transmitting element and smaller than the second space.

8. A vibration device comprising:
a vibrator;
a piezoelectric element at a first end of the vibrator in a first direction;
a light-transmitting element at a second end of the vibrator in the first direction;
a holding portion that holds the second end of the vibrator and the light-transmitting element in the first direction;
a first member between the light-transmitting element and the holding portion and connected to the light-transmitting element and the holding portion; and
a second member between the light-transmitting element and the vibrator and connected to the light-transmitting element and the vibrator,
wherein a Young's modulus of the first member is equal to or less than a Young's modulus of the second member.

9. The vibration device according to claim 8, wherein a thickness of the first member is equal to or more than a thickness of the second member.

10. The vibration device according to claim 8, wherein the second member contains an adhesive material.

11. The vibration device according to claim 8, wherein the first member contains a waterproof material.

12. The vibration device according to claim 8, further comprising:
an outer vibrator, wherein the outer vibrator includes:
a first connection portion that includes the holding portion and is connected to the light-transmitting element via the holding portion,
a second connection portion extending from the first connection portion in a direction away from the light-transmitting element along a direction crossing the first direction, and
a fixing portion connected the second connection portion on an end thereof opposite to the first connection portion; and
a stopper portion connected to the fixing portion in a state in which the second connection portion is able to come into contact with the stopper portion and a first space is defined between the stopper portion and the second connection portion in the first direction.

13. The vibration device according to claim 12, wherein
the stopper portion has an inclined surface facing the second connection portion in the first direction, and
the inclined surface is inclined away from the second connection portion in the first direction toward the first connection portion in the direction crossing the first direction.

14. The vibration device according to claim 12, wherein
the fixing portion surrounds the vibrator around an optical axis of the light-transmitting element, and
the stopper portion has an annular shape extending in a circumferential direction around the optical axis.

15. The vibration device according to claim 12, wherein
the fixing portion surrounds the vibrator around an optical axis of the light-transmitting element, and
the stopper portion includes a plurality of members spaced from each other in a circumferential direction around the optical axis.

16. The vibration device according to claim 12, wherein the fixing portion and the stopper portion are integral.

17. The vibration device according to claim 12, wherein
the fixing portion has a first facing surface facing and spaced from the second connection portion in the first direction, and
the stopper portion is connected to the first facing surface.

18. The vibration device according to claim 12, wherein
the fixing portion has a second facing surface facing and spaced from the vibrator in the direction crossing the first direction, and
the stopper portion is connected to the second facing surface.

19. The vibration device according to claim 12, wherein
the stopper portion includes a first layer and a second layer laminated in the first direction, and
the first layer is closer to the second connection portion than the second layer and has a lower elastic modulus than the second layer.

20. The vibration device according to claim 12, further comprising:
a lens module inside the vibrator and defining a second space between the light-transmitting element and the lens module,
wherein the first space has a size equal to or larger than a maximum amplitude of the light-transmitting element and smaller than the second space.
